(19) United States
(12) Patent Application Publication
(10) Pub. No.: US 2026/0032894 A1
(43) Pub. Date: Jan. 29, 2026

(54) SEMICONDUCTOR STRUCTURE AND MANUFACTURING METHOD THEREFOR, AND SEMICONDUCTOR DEVICE

(71) Applicant: CXMT Corporation, Hefei City (CN)

(72) Inventor: Yibo WANG, Hefei City (CN)

(73) Assignee: CXMT Corporation, Hefei City (CN)

(21) Appl. No.: 18/945,484

(22) Filed: Nov. 12, 2024

Related U.S. Application Data
(63) Continuation of application No. PCT/CN2024/126304, filed on Oct. 22, 2024.

(30) Foreign Application Priority Data
Jul. 26, 2024 (CN) 202411022419.7

(51) Int. Cl. H10B 12/00

(52) U.S. Cl. CPC H10B 12/50; H10B 12/09

(57) ABSTRACT

A semiconductor structure and a manufacturing method therefor, and a semiconductor device are provided. The semiconductor structure includes a substrate, and the substrate includes a storage region, a peripheral region, and a transition region located between the storage region and the peripheral region. The transition region includes a first isolation structure. The semiconductor structure further includes a first trench, which is located in the isolation structure. The first trench extends in a first direction, and a depth of the first trench is less than a depth of the isolation structure.

### CROSS REFERENCE TO RELATED APPLICATIONS

This application is a continuation of International Patent Application No. PCT/CN2024/126304 filed on Oct. 22, 2024, which claims priority to Chinese Patent Application No. 202411022419.7 filed on Jul. 26, 2024. The disclosures of the above-referenced applications are hereby incorporated by reference in their entirety.

### BACKGROUND

Dynamic random access memories (DRAMs) are semiconductor memories widely applied to multi-computer systems.

With continuous development of a semiconductor manufacturing process, a size of the semiconductor memory is becoming smaller. Especially, as a process node of the DRAM becomes smaller, a feature size of a word line is constantly miniaturized, a manufacturing process of the word line becomes more complex, and distortion of an end of the word line is generated accordingly, thereby adversely affecting performance of the DRAM.

### SUMMARY

Embodiments of the present disclosure relate to the field of semiconductor technologies, and in particular, to a semiconductor structure and a manufacturing method therefor, and a semiconductor device.

According to a first aspect of embodiments of the present disclosure, a semiconductor structure is provided, including:
a substrate, including a storage region, a peripheral region, and a transition region located between the storage region and the peripheral region, the transition region including a first isolation structure; and
a first trench, located in the isolation structure, the first trench extending in a first direction, and a depth of the first trench being less than a depth of the isolation structure.

According to a second aspect of the embodiments of the present disclosure, a semiconductor device is provided, including:
a substrate, including a storage region, a peripheral region, and a transition region located between the storage region and the peripheral region, the transition region including a first isolation structure;
a first trench, located in the first isolation structure, the first trench extending in a first direction, and a depth of the first trench being less than a depth of the isolation structure;
a second trench extending in a second direction from the storage region into the transition region; and
a word line conductive layer, located in the second trench;
the first trench being in communication with the second trench.

According to a third aspect of the embodiments of the present disclosure, a manufacturing method for a semiconductor structure is provided, including:
providing a substrate, the substrate including a storage region, a peripheral region, and a transition region located between the storage region and the peripheral region, and the transition region including a first isolation structure; and
forming a first trench in the first isolation structure, a depth of the first trench being less than a depth of the first isolation structure.

### BRIEF DESCRIPTION OF DRAWINGS

FIG. 1 is an electron microscope diagram of a trench in a related technology according to an example embodiment;

FIG. 2 is a flowchart of a manufacturing method for a semiconductor structure according to an example embodiment;

FIG. 3 is a top view of a substrate according to an example embodiment;

FIG. 4 is a cross-sectional view of FIG. 3 in an AA direction according to an example embodiment;

FIG. 5 is a schematic diagram of a patterned photoresist layer according to an example embodiment;

FIG. 6 is another schematic diagram of a substrate according to an example embodiment;

FIG. 7A is a cross-sectional view of FIG. 6 in an AA direction according to an example embodiment;

FIG. 7B is a schematic diagram of a first trench according to an example embodiment;

FIG. 8 is another schematic diagram of a substrate according to an example embodiment;

FIG. 9 is a cross-sectional view of FIG. 9 in an AA direction according to an example embodiment;

FIG. 10 is a cross-sectional view of FIG. 9 in a BB direction according to an example embodiment;

FIG. 11 is another schematic diagram of a first trench according to an example embodiment;

FIG. 12 is another schematic diagram of a substrate according to an example embodiment;

FIG. 13 is a cross-sectional view of FIG. 12 in an AA direction according to an example embodiment;

FIG. 14 is another schematic diagram of a substrate according to an example embodiment;

FIG. 15 is a cross-sectional view of FIG. 14 in an AA direction according to an example embodiment;

FIG. 16 is another schematic diagram of a substrate according to an example embodiment;

FIG. 17 is a cross-sectional view of FIG. 16 in an AA direction according to an example embodiment;

FIG. 18 is another cross-sectional view of FIG. 16 in an AA direction according to an example embodiment;

FIG. 19 is a schematic diagram of forming a protective layer according to an example embodiment; and

FIG. 20 is an electron microscope diagram of FIG. 8 according to an example embodiment.

### DETAILED DESCRIPTION

The technical solutions of the present disclosure are further described below in detail with reference to the accompanying drawings and the embodiments. Although example implementations of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily indicate a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. Multiple sublayers may be included in the layer.

It should be noted that the technical solutions described in the embodiments of the present disclosure may be randomly combined when there is no conflict.

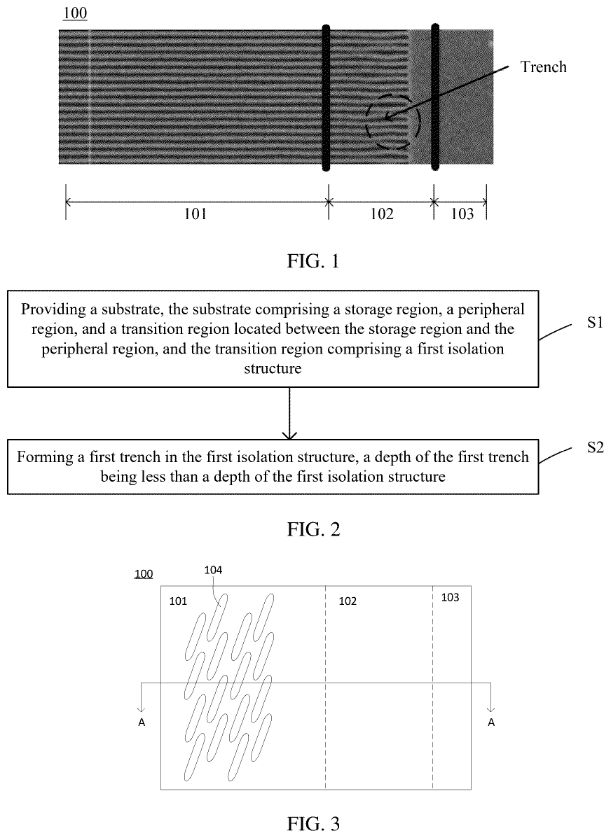

As shown in FIG. 1, FIG. 1 is an electron microscope diagram of a trench in a related technology. FIG. 1 is an electron microscope diagram of forming a trench in a substrate 100. The substrate 100 may include a storage region 101, a transition region 102, and a peripheral region 103. The trench on the substrate 100 extends from the storage region 101 into the transition region 102, that is, an end of the trench is located in the transition region 102. It can be seen from FIG. 1 that the trenches in the storage region 101 are neat and straight. A trench in the transition region 102 is distorted, that is, an end of the trench is deformed, thereby affecting performance of a device.

It is found through research in the present disclosure that, in a process of forming the trench, an etching gas gradually consumes the substrate, thereby gradually forming the trench. Near the end of the trench, due to a blocking effect of an unconsumed substrate, an etching gas above the end of the trench is disturbed and concentrated, and consequently the end of the trench is etched at different rates, thereby causing deformation of the end of the trench. In addition, because the end of the trench is closed, a large stress concentrates at the end of the trench, thereby aggravating deformation of the end of the trench.

Therefore, as shown in FIG. 2, an embodiment of the present disclosure provides a manufacturing method for a semiconductor structure. The manufacturing method can alleviate deformation of an end of a trench and improve performance of the semiconductor structure.

In the step of S1, a substrate is provided, where the substrate includes a storage region, a peripheral region, and a transition region located between the storage region and the peripheral region, and the transition region includes a first isolation structure.

In the step of S2, a first trench is formed in the first isolation structure, where a depth of the first trench is less than a depth of the first isolation structure.

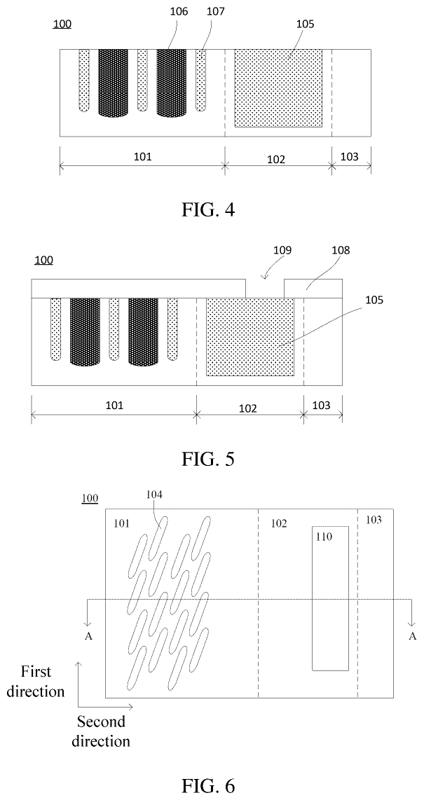

As shown in FIG. 3 and FIG. 4, FIG. 3 is a top view of a substrate 100, and FIG. 4 is a cross-sectional view of FIG. 3 in an AA direction. The substrate 100 may successively include a storage region 101, a transition region 102, and a peripheral region 103. The substrate 100 may be a single-layer structure, or may be a multi-layer structure. For example, the substrate 100 may be a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate, or another III/V semiconductor substrate or II/VI semiconductor substrate. Alternatively, the substrate 100 may be a layered substrate including Si/SiGe, Si/SiC, silicon on insulator (SOI), silicon germanium on insulator, or the like. The storage region 101 includes an active region 104. The storage region 101 may be configured to form a word line structure, a bit line structure, a capacitor structure, and the like. The peripheral region 103 is configured to form a peripheral circuit structure.

As shown in FIG. 4, the transition region 102 may be configured to separate the storage region 101 from the peripheral region 103, thereby forming a first isolation structure 105 in the transition region 102. In addition, to form the active region 104 in the storage region 101, the storage region 101 includes a second isolation structure 106 and a third isolation structure 107. In the AA direction, a width of the first isolation structure 105 is greater than a width of the second isolation structure 106, and the width of the second isolation structure 106 is greater than a width of the third isolation structure 107. In a vertical direction, a depth of the first isolation structure 105 is greater than a depth of the second isolation structure 106, and the depth of the second isolation structure 106 is greater than a depth of the third isolation structure 107. Because the width and the depth of the first isolation structure 105 are large, the storage region 101 and the peripheral region 103 are effectively isolated. In addition, because the width of the first isolation structure 105 is large, an end of a trench formed subsequently may be located in the first isolation structure 105, thereby effectively preventing the end of the trench from extending into the peripheral region 103. In some embodiments, the first isolation structure 105, the second isolation structure 106, and the third isolation structure 107 may be all shallow trench isolation structures. The first isolation structure 105 may be filled with silicon oxide, the second isolation structure 106 may be filled with silicon nitride, and the third isolation structure 107 may be filled with silicon oxide.

As shown in FIG. 5 to FIG. 7A, in the step of S2, a patterned photoresist layer 108 is first formed on the substrate 100, the patterned photoresist layer 108 covers the storage region 101 and the peripheral region 103, there is an opening 109 in the patterned photoresist layer 108, and the opening 109 exposes the first isolation structure 105. Then, the first isolation structure 105 is etched by the etching gas through the opening 109 with the patterned photoresist layer 108 as a mask, so that a first trench 110 is formed in the first isolation structure 105. Because the first isolation structure 105 extends in a first direction, the first trench 110 extends in the first direction. In addition, because the first isolation structure 105 is not completely etched, in a second direction (an AA direction), a width of the first trench 110 is less than a width of the first isolation structure 105, and in a vertical direction, a depth of the first trench 110 is less than a depth of the first isolation structure 105.

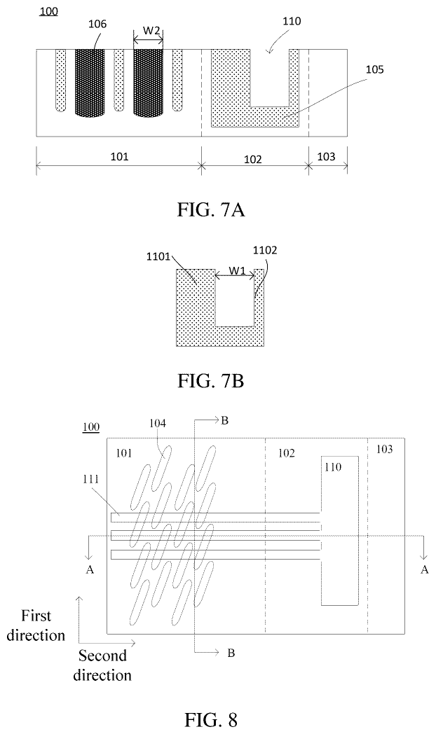

As shown in FIG. 6 to FIG. 7B, the first trench 110 may include a first sidewall 1101 and a second sidewall 1102. The first sidewall 1101 is close to the storage region 101, and the second sidewall 1102 is close to the peripheral region 103. In the second direction, a width of the first sidewall 1101 is greater than a width of the second sidewall 1102. In other words, the first trench 110 is not located at a central position of the first isolation structure 105, that is, in the second direction, the first trench 110 is closer to the peripheral region 103. In addition, in the second direction, an opening width W1 of the first trench 110 is greater than a width W2 of the second isolation structure 106. If the opening width W1 of the first trench 110 is small, when a word line trench is formed in the storage region 101 and the transition region 102, the etching gas may be further blocked by the second sidewall 1102, thereby causing bending of an end of the word line trench. In this embodiment of the present disclosure, the opening width W1 of the first trench 110 is increased, so that impact of the second sidewall 1102 on the etching gas can be effectively reduced, and further neatness of the end of the word line trench can be ensured.

As shown in FIG. 8, FIG. 8 is a top view of the second trench 111. After the first trench 110 is formed, the second trench 111 may be further formed on the substrate 100. The second trench 111 extends from the storage region 101 into the transition region 102, that is, an end of the second trench 111 is located in the transition region 102. In addition, when extending into the first isolation structure 105, the end of the second trench 111 is in communication with the first trench 110. FIG. 8 shows multiple second trenches 111, which are insulated from each other and are all in communication with the first trench 110. In the first direction, a length of the first trench 110 is greater than a length of each second trench 110, and is also greater than a sum of lengths of all the second trenches 110, thereby ensuring that all the second trenches 111 are all in communication with the first trench 110. In the second direction, the second trench 111 is basically perpendicular to the first trench 110.

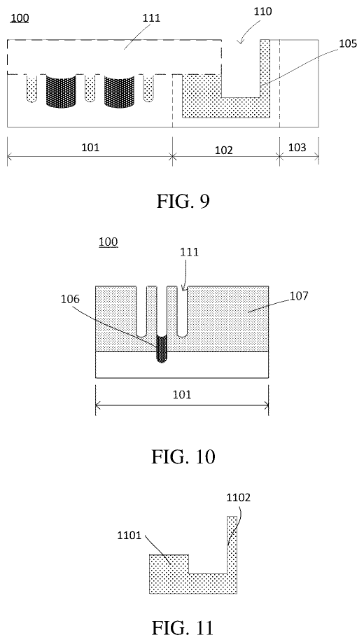

As shown in FIG. 9, FIG. 9 is a cross-sectional view of FIG. 8 in an AA direction. To display a relationship between the first trench 110 and the second trench 111, the second trench 111, that is, the position in the dashed-line box in FIG. 9, is displayed in FIG. 9. The substrate of the storage region 101 and the first sidewall 1101 of the first trench 110 are etched by the etching gas to form the second trench 111. In addition, because the first sidewall 111 is etched, the first trench 110 is in communication with the second trench 111. In this embodiment, during formation of the second trench 111, the first trench 110 has been formed in the first isolation structure 105, and the second sidewall 1102 is far away from the first sidewall 1101. Therefore, a blocking effect of the first trench 110 on the etching gas may be alleviated, thereby improving neatness of the end of the second trench 111. In addition, because the first trench 110 is in communication with the second trench 111, that is, the end of the second trench 111 is open, it is conducive to releasing a stress at the end of the second trench 111, thereby further improving neatness of the end of the second trench 111.

As shown in FIG. 9, in this embodiment, a bottom surface of the first trench 110 is lower than a bottom surface of the second trench 111, that is, in the vertical direction, a depth of the first trench 110 is greater than a depth of the second trench 110, so that the bottom surface of the first trench 110 can be prevented from generating a blocking effect on the etching gas, thereby ensuring neatness of the second trench 110.

As shown in FIG. 10, FIG. 10 is a cross-sectional view of FIG. 8 in a BB direction. In the first direction, the second trenches 111 are separated from each other. These second trenches 111 are isolated from each other by the third isolation structure 107. The second trench 111 runs through the second isolation structure 106 and the third isolation structure 107. In the vertical direction, a depth of the second trench 111 is less than a depth of the second isolation structure 106, and the depth of the second trench 111 is less than a depth of the third isolation structure 107, so as to prevent the second trench 111 from extending into the active region and prevent a short circuit. In some embodiments, the second trench 111 may be a word line trench.

As shown in FIG. 11, during formation of the second trench 111, a part of the first sidewall 1101 is etched, so that a height of the first sidewall 1101 is reduced. To be specific, in the vertical direction, a top surface of the first sidewall 1101 is lower than a top surface of the second sidewall 1102, the top surface of the first sidewall 1101 is higher than a bottom surface of the second trench 111, the top surface of the first sidewall 1101 is flush with a top surface of the storage region 101, and the top surface of the second sidewall 1102 is further flush with a top surface of the peripheral region 103.

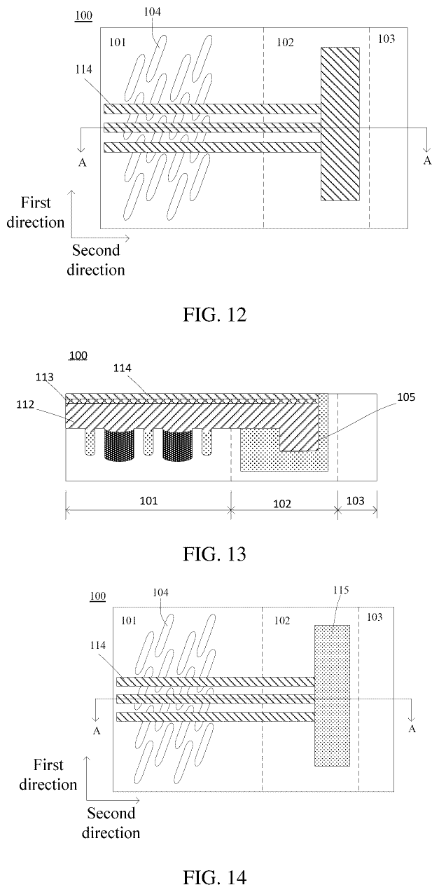

As shown in FIG. 12, FIG. 12 is a top view after a word line conductive layer 114 is formed. After the second trench 111 is formed, a word line conductive layer 112 may be further formed in the second trench 111, and then a second conductive layer 113 is formed on the word line conductive layer 112, and a protective layer 114 is formed on the second conductive layer 113. The word line conductive layer 112 basically completely fills the second trench 111 and the first trench 110. After the protective layer 114 is formed, a top surface of the protective layer 114 is flush with the top surface of the peripheral region 103.

As shown in FIG. 13, FIG. 13 is a cross-sectional view of FIG. 12 in an AA direction. It can be seen from FIG. 13 that the word line conductive layer 112 extends from the storage region 101 into the transition region 102. The word line conductive layer 112 covers the first sidewall 1101, and a top surface of the word line conductive layer 112 is lower than the top surface of the second sidewall 1102. The second conductive layer 113 basically covers the word line conductive layer 112, and the protective layer 114 basically covers the second conductive layer 113. In the vertical direction, a thickness of the second conductive layer 113 is less than a thickness of the word line conductive layer 112. The second conductive layer 113 and the word line conductive layer 112 are made of different materials, and have different work functions. The material of the word line conductive layer 112 may include but is not limited to arsenic (As) or boron (B) doped silicon, phosphorus (P) or As doped germanium, tungsten (W), titanium (Ti), titanium nitride (TiN), or gold (Au). The material of the second conductive layer 113 may include but is not limited to polysilicon. In this embodiment, a thickness of the protective layer 114 is greater than the thickness of the second conductive layer 113, and a top surface of the protective layer 114 is flush with the top surface of the peripheral region 103. The protective layer 114 may be configured to protect the second conductive layer 113. A material of the protective layer 114 may include but is not limited to silicon oxide, silicon nitride, or silicon oxynitride.

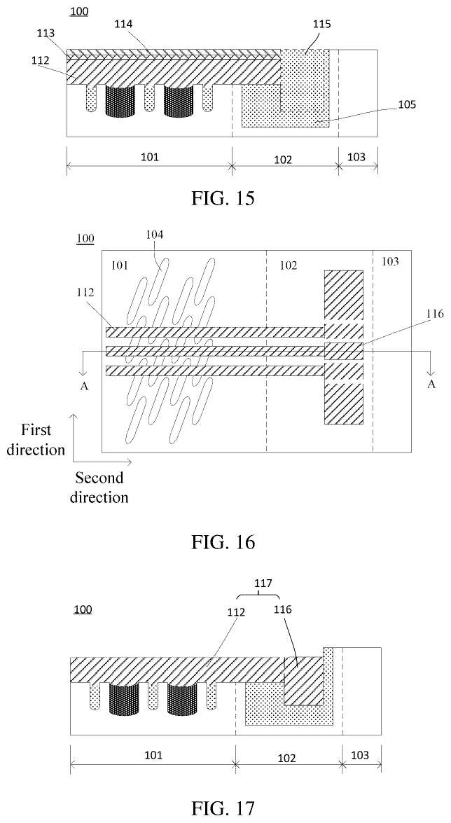

As shown in FIG. 14 and FIG. 15, FIG. 14 is a top view of forming an insulating layer 115, and FIG. 15 is a cross-sectional view of FIG. 14 in an AA direction. To show a structure of the insulating layer 115, the insulating layer 115 is represented in a dashed-line box in FIG. 15. In some embodiments, after the protective layer 114 is formed, the protective layer 114, the second conductive layer 113, and the word line conductive layer 112 that are located in the first trench 110 may be further etched. In other words, the protective layer 114, the second conductive layer 113, and the word line conductive layer 112 that are located in the second trench 111 are retained. After the protective layer 114, the second conductive layer 113, and the word line conductive layer 112 in the first trench 110 are removed, the first trench 110 may be further filled with the insulating layer 115. A top surface of the insulating layer 115 may be flush with the top surface of the peripheral region 103. Because the first trench 110 is in communication with the second trench 111, the word line conductive layer 112 in the first trench 110 is also in communication with the word line conductive layer 112 in the second trench 111. The word line conductive layer 112 in the first trench 110 is removed, and the word line conductive layer 112 in the second trench 111 is retained, thereby ensuring that the word line conductive layer 112 is located only in the second trench 111. Because the second trench 111 is isolated, it can be ensured that the word line conductive layer 112 located in the second trench 111 is also isolated. Because the first trench 110 includes an insulating layer 115, and a top surface of the insulating layer 115 is higher than a top surface of the word line conductive layer 112, these word line conductive layers 112 may be prevented from being connected. In this embodiment, the word line conductive layer 112, the second protective layer 113, and the protective layer 114 may be defined as a word line structure.

As shown in FIG. 16, FIG. 16 is a top view of forming a word line contact layer 1122. In some embodiments, after the word line conductive layer 112 is formed, the word line conductive layer 112 located in the first trench 110 is etched to form a word line contact layer 116. In addition, the word line conductive layer 112 in the second trench 111 is retained. It can be seen from FIG. 16 that, in this embodiment, the word line conductive layer 112 in the first trench 110 is not completely etched. In the first direction, the second trenches 112 are separated by the third isolation structure 107. In this embodiment of the present disclosure, a part of the word line conductive layer 112 corresponding to the third isolation structure 107 in the first trench 110 is etched, so that the word line conductive layer 112 is divided into multiple word line contact layers 116, and then a gap between the word line contact layers 116 is filled with an insulating material to isolate the word line contact layers 116. The word line contact layer 116 is connected to the word line conductive layer 112. In this embodiment, the word line contact layer 116 and the word line conductive layer 112 may be defined as a word line body layer 117. Because these word line contact layers 116 are separated and insulated from each other, and the word line conductive layers 112 are separated and insulated from each other, these word line body layers 117 are insulated and independent from each other.

As shown in FIG. 16, in the first direction, a width of the etched word line conductive layer 112 in the first trench 110 is less than the width of the third isolation structure 107, and therefore, a width of the word line contact layer 116 is greater than a width of the word line conductive layer 112. In the first direction, a gap between the word line contact layers 116 is less than a gap between the word line conductive layers 112. In this embodiment, the gap between the word line conductive layers 112 may be greater than the gap between the word line contact layers 116 by 5-7 nm. If the gap between the word line contact layers 116 is excessively small, it is not conducive to filling an insulating material within the word line contact layers 116. The first direction may be perpendicular to the second direction. From a top view, the first direction may be a vertical direction, and the second direction may be a horizontal direction.

As shown in FIG. 17, FIG. 17 is a cross-sectional view of FIG. 16 in an AA direction. The word line conductive layer 112 is connected to the word line contact layer 116, and a top surface of the word line conductive layer 112 is flush with a top surface of the word line contact layer 116. Certainly, the second conductive layer 113 and the protective layer 114 may be further formed on the word line body layer 117, so as to form a word line structure.

As shown in FIG. 15 and FIG. 17, in FIG. 15, the first trench 110 is completely filled with the insulating layer 115. In FIG. 17, the first trench 110 includes a word line contact layer 116, and the word line contact layer 116 is connected to the word line conductive layer 112. After the word line structure is formed, an interconnection pillar further needs to be formed, and the interconnection pillar is connected to the word line structure, so as to provide a signal for the word line structure. It is found in this embodiment of the present disclosure that, when an interconnection pillar is formed in the transition region 102, the structure in FIG. 15 is employed, and if a position of the interconnection pillar is offset, the interconnection pillar is offset into the storage region 101. In addition, because a part of the word line conductive layer 112 is etched by the etching gas, the interconnection pillar may be in communication with the active region in the storage region 101, thereby forming a short circuit. However, when the interconnection pillar is formed by employing the structure in FIG. 17, the interconnection pillar may be formed on the word line contact layer 116, and the word line contact layer 116 is far away from the storage region 101. Therefore, the interconnection pillar is not easily offset toward the storage region 101. In addition, a depth of the word line contact layer 116 is greater than a depth of the word line conductive layer 112, and an insulating material is located below the word line contact layer 116. Therefore, even if the word line contact layer 116 is etched, the word line contact layer 116 is not in contact with the active region, thereby preventing a short circuit between the interconnection pillar and the active region. Again, in the first direction, a width of the word line contact layer 116 is greater than a width of the word line conductive layer 112. Therefore, an offset range of the interconnection pillar may be expanded, or a contact area between the word line contact layer 116 and the interconnection pillar may be expanded to reduce a contact resistance.

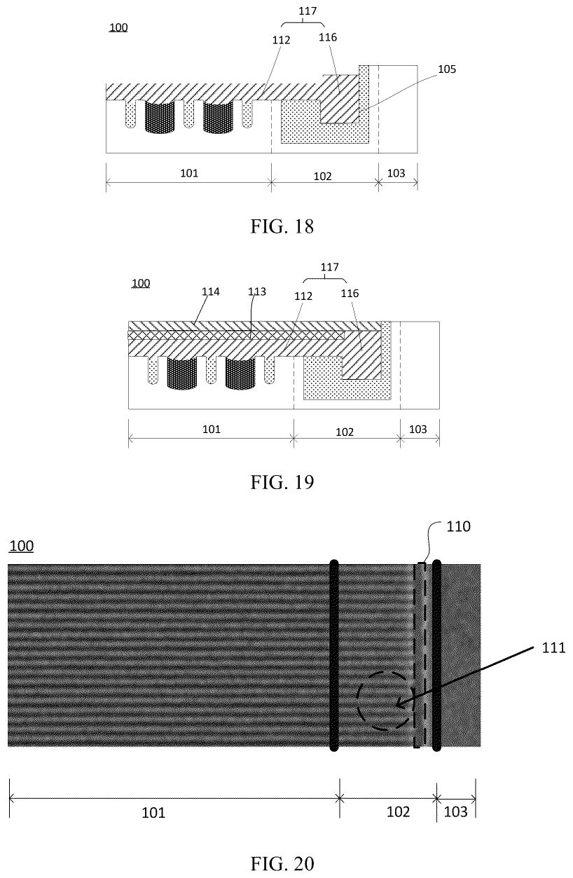

As shown in FIG. 18 and FIG. 19, FIG. 18 is another cross-sectional view of FIG. 16 in an AA direction. In FIG. 18, the word line conductive layer 112 is connected to the word line contact layer 116, and a top surface of the word line conductive layer 112 is lower than a top surface of the word line contact layer 116. There is further a second conductive layer 113 on the word line conductive layer 112, and a top surface of the second conductive layer 113 is flush with the top surface of the word line contact layer 116. There is further a protective layer 114 on the second conductive layer 113, and the protective layer 114 further covers the word line contact layer 116, so that a top surface of the protective layer 114 is flush with the top surface of the word line contact layer 116. In this embodiment, the word line conductive layer 112 and the word line contact layer 116 may be defined as a word line body layer 117. The word line main layer 117, the second conductive layer 113, and the protective layer 114 may be defined as a word line structure.

As shown in FIG. 17 and FIG. 18, in FIG. 17, the top surface of the word line conductive layer 112 is flush with the top surface of the word line contact layer 116. When an interconnection pillar is formed on the word line contact layer 116, a depth of the interconnection pillar is large, and a required etching time is long. In FIG. 18, the top surface of the word line conductive layer 112 is lower than the top surface of the word line contact layer 116. Therefore, the depth of the interconnection pillar can be reduced, the etching time can be shortened, impact on a sidewall of an interconnection hole can be alleviated, and short-circuiting between interconnection pillars can be alleviated.

As shown in FIG. 20, FIG. 20 is an electron microscope diagram of FIG. 8. A rectangular dashed-line box displays the first trench 110, and a circular dashed-line box displays the end of the second trench 111. In comparison with FIG. 1, the end of the second trench 111 in FIG. 20 is in communication with the first trench 110, and the end of the second trench 111 is neat and straight. Therefore, the manufacturing method in this embodiment of the present disclosure can effectively alleviate bending of the end of the second trench 111, and improve performance of the semiconductor structure.

As shown in FIG. 8 and FIG. 9, an embodiment of the present disclosure provides a semiconductor structure. The semiconductor structure may include a substrate 100. The substrate 100 may include a storage region 101, a transition region 102, and a peripheral region 103. The peripheral region 103 includes a first isolation structure 105, and the first isolation structure 105 includes a first trench 110. The first trench 110 extends in a first direction, and a depth of the first trench 110 is less than a depth of the first isolation structure 105. The first trench 110 may include a first sidewall 1101 and a second sidewall 1102. The first sidewall 1101 is close to the storage region 101, and the second sidewall 1102 is close to the peripheral region 103. A top surface of the first sidewall 1101 is lower than a top surface of the second sidewall 1102. The top surface of the first sidewall 1101 is higher than a bottom surface of the second trench, and the top surface of the second sidewall 1102 is flush with a top surface of the storage region. In a second direction, a width of the first sidewall 1101 is greater than a width of the second sidewall 1102, thereby increasing a distance between the second sidewall 1102 and the storage region 101, and alleviating a blocking effect of the second sidewall 1102 on an etching gas. Before the second trench 111 is formed, the first trench 110 is first formed in the first isolation structure 105. Therefore, during formation of the second trench 111, the blocking effect of the second sidewall 1102 on the etching gas can be alleviated, and concentration of the etching gas on the end of the second trench 111 can be alleviated, thereby ensuring neatness of the end of the second trench 111. In addition, because the end of the second trench 111 is in communication with the first trench 110, an end stress of the second trench 111 may be released, thereby alleviating distortion of the second trench 111. The substrate 100 includes the second trench 111, and the second trench 111 extends in the second direction from the storage region 101 into the transition region 102, so as to be in communication with the first trench 110. The first trench 110 is basically perpendicular to the second trench 111.

As shown in FIG. 8 to FIG. 11, in a vertical direction, a depth of the first trench 110 is greater than a depth of the second trench 111, thereby preventing the end of the second trench 111 from being blocked by a bottom surface of the first trench 110, and further improving neatness of the end of the second trench 111. The storage region 101 further includes a second isolation structure 106, and the second trench 111 runs through the second isolation structure 106. A width W2 of the second isolation structure 106 is less than an opening width W1 of the first trench 110, thereby alleviating a blocking effect of the second sidewall 1102 on the etching gas, and improving straightness of the end of the second trench 111. In the vertical direction, a depth of the first trench 110 is less than a depth of the second isolation structure 106, and there is a specific distance between the first trench 110 and an active region below the first trench 110, thereby preventing a short-circuit problem.

As shown in FIG. 15, an embodiment of the present disclosure provides a semiconductor device. The semiconductor device includes a substrate 100, and the substrate 100 may include a storage region 101, a transition region 102, and a peripheral region 103. The transition region 102 includes a first isolation structure 105. A first trench 110 is located in the first isolation structure 105, and a second trench 111 extends in a second direction from the storage region 101 into the transition region 102, so as to be in communication with the first trench 110. The second trench 111 includes a word line conductive layer 112. The first trench 110 is filled with an insulating layer 115, and a top surface of the insulating layer 115 is higher than a top surface of the word line conductive layer 112. An end of the second trench 111 is neat.

As shown in FIG. 16 to FIG. 18, an embodiment of the present disclosure provides another semiconductor device. The semiconductor device differs from that in FIG. 15 in that, in FIG. 16 to FIG. 18, the first trench 110 includes a word line contact layer 116, and the word line contact layer 116 is connected to the word line conductive layer 112. In a direction parallel to the first direction, a width of the word line contact layer 116 is greater than a width of the word line conductive layer 112. In the direction parallel to the first direction, a gap between adjacent word line contact layers 116 is less than a gap between adjacent word line conductive layers 112. In FIG. 17, a top surface of the word line conductive layer 112 is flush with a top surface of the word line contact layer 116, and a bottom surface of the word line conductive layer 112 is higher than a bottom surface of the word line contact layer 116. In FIG. 18, the top surface of the word line contact layer 116 is higher than the top surface of the word line conductive layer 112. The word line contact layer 116 is located between a first sidewall 1101 and a second sidewall 1102, and the top surface of the word line contact layer 116 exceeds the first sidewall 1101 and is lower than the second sidewall 1102. For a function of the word line contact layer 116, reference may be made to the foregoing description.

The foregoing semiconductor device may be applied to an electronic device. The electronic device may include one or more of the following: e.g., a smart phone, a tablet personal computer (PC), a mobile phone, a video phone, an e-book (e-book) reader, a desktop PC, a laptop PC, a netbook computer, a workstation, a server, a personal digital assistant (PDA), a portable multimedia player (PMP), an MPEG-1 audio layer 3 (MP3) player, a mobile medical device, a camera, a home appliance, a medical device, an Internet of Things (IoT) device, and a wearable device. The wearable device may be of an accessory type, a fabric or clothing type, a body attachment type, or an implantable circuit type. An accessory-type wearable device may be, e.g., a watch, a ring, a bracelet, an anklet, a necklace, glasses, contact lenses, or a head-mounted device (HMD).

In conclusion, the embodiments of the present disclosure provide a semiconductor structure and a manufacturing method therefor, and a semiconductor device. In the embodiments of the present disclosure, the first trench is first formed in the first isolation structure in the transition region, and then the second trench is formed, so that the blocking effect of the first isolation structure on the etching gas can be alleviated, and the etching gas near the end of the second trench is relatively uniform, thereby improving neatness of the end of the second trench and alleviating an end distortion problem.

In addition, because the second trench is in communication with the first trench, the end stress of the second trench may be released, thereby alleviating an end bending problem of the second trench, and improving performance of the semiconductor structure.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A semiconductor structure, comprising:
a substrate, comprising a storage region, a peripheral region, and a transition region located between the storage region and the peripheral region, the transition region comprising a first isolation structure; and
a first trench, located in the isolation structure, the first trench extending in a first direction, and a depth of the first trench being less than a depth of the isolation structure.

2. The semiconductor structure according to claim 1, wherein the first trench comprises:
a first sidewall near the storage region; and
a second sidewall near the peripheral region;
a width of the first sidewall being greater than a width of the second sidewall.

3. The semiconductor structure according to claim 2, further comprising:
a second trench extending in a second direction from the storage region into the transition region;
the first trench being in communication with the second trench.

4. The semiconductor structure according to claim 3, wherein the depth of the first trench is greater than a depth of the second trench.

5. The semiconductor structure according to claim 3, further comprising:
a second isolation structure, the second trench running through the second isolation structure;
in the second direction, a width of the first trench being greater than a width of the second isolation structure.

6. The semiconductor structure according to claim 5, wherein the depth of the first trench is less than a depth of the second isolation structure.

7. The semiconductor structure according to claim 3, wherein a top surface of the first sidewall is lower than a top surface of the second sidewall, the top surface of the first sidewall is higher than a bottom surface of the second trench, and the top surface of the first sidewall is flush with a top surface of the storage region.

8. A semiconductor device, comprising:
a substrate, comprising a storage region, a peripheral region, and a transition region located between the storage region and the peripheral region, the transition region comprising a first isolation structure;
a first trench, located in the first isolation structure, the first trench extending in a first direction, and a depth of the first trench being less than a depth of the isolation structure;
a second trench extending in a second direction from the storage region into the transition region; and
a word line conductive layer, located in the second trench;
the first trench being in communication with the second trench.

9. The semiconductor device according to claim 8, further comprising:
an insulating layer basically filling the first trench;
a top surface of the insulating layer being higher than a top surface of the word line conductive layer.

10. The semiconductor device according to claim 8, further comprising:
a word line contact layer, located in the first trench;
the word line contact layer being connected to the word line conductive layer.

11. The semiconductor device according to claim 10, wherein in a direction parallel to the first direction, a width of the word line contact layer is greater than a width of the word line conductive layer.

12. The semiconductor device according to claim 10, wherein in a direction parallel to the first direction, a gap between adjacent word line contact layers is less than a width between adjacent word line conductive layers.

13. The semiconductor device according to claim 10, wherein a bottom surface of the word line contact layer is lower than a bottom surface of the word line conductive layer.

14. The semiconductor device according to claim 10, wherein a top surface of the word line contact layer is higher than a top surface of the word line conductive layer.

15. The semiconductor device according to claim 10, wherein the first trench comprises:
a first sidewall near the storage region; and
a second sidewall away from the storage region;
in a direction parallel to the second direction, a width of the first sidewall being greater than a width of the second sidewall.

16. The semiconductor device according to claim 15, wherein the word line contact layer is located between the first sidewall and the second sidewall, and a top surface of the word line contact layer exceeds the first sidewall and is lower than the second sidewall.

17. A manufacturing method for a semiconductor structure, comprising:
providing a substrate, the substrate comprising a storage region, a peripheral region, and a transition region located between the storage region and the peripheral region, and the transition region comprising a first isolation structure; and
forming a first trench in the first isolation structure, a depth of the first trench being less than a depth of the first isolation structure.

18. The manufacturing method according to claim 17, further comprising:
etching the storage region and a part of the first isolation structure to form a second trench, the second trench extending in a second direction from the storage region into the transition region;
the first trench being in communication with the second trench, the first trench being basically perpendicular to the second trench, and a depth of the second trench being less than a depth of the first trench.

19. The manufacturing method according to claim 18, further comprising:
forming a word line conductive layer in the second trench; and
forming an insulating layer in the first trench;
a top surface of the insulating layer being higher than a top surface of the word line conductive layer.

20. The manufacturing method according to claim 18, further comprising:
forming a word line conductive layer in the second trench, and forming a word line contact layer in the first trench;
the word line conductive layer being connected to the word line contact layer;
in a first direction, a width of the word line contact layer being greater than a width of the word line conductive layer.
